(19) United States
(12) Patent Application Publication
(10) Pub. No.: US 2015/0228358 A1
(43) Pub. Date: Aug. 13, 2015

(54) INFORMATION PROCESSING DEVICE AND MEMORY TEST METHOD

(71) Applicant: FUJITSU LIMITED, Kawasaki-shi (JP)

(72) Inventors: Masashi AGATA, Kawasaki (JP); Daisuke HARADA, Kawasaki (JP)

(73) Assignee: FUJITSU LIMITED, Kawasaki (JP)

(21) Appl. No.: 14/690,769

(22) Filed: Apr. 20, 2015

Related U.S. Application Data
(63) Continuation of application No. PCT/JP2012/078255, filed on Oct. 31, 2012.

(51) Int. Cl. G11C 29/10; G01R 31/3181

(52) U.S. Cl. CPC G11C 29/10; G01R 31/31813

(57) ABSTRACT

An information processing device includes a storage unit and a processor. The storage unit stores margin information, which stores a specified margin indicating a length of time in which signal processing is operated normally, in association with the type of a memory and the operation environment. The processor causes the memory to perform signal processing. The processor also changes an operation timing and specifies a range of operation timings with which the signal processing may be performed normally. Furthermore, the processor acquires the specified range of the operation timing as a measured margin, and extracts a specified margin associated with a combination of the type of memory and the operation environment of a current information processing device from the margin information. Then, the processor judges that the memory is not operating normally in the information processing device when the acquired measured margin is shorter than the extracted specified margin.

### CROSS-REFERENCE TO RELATED APPLICATION

This application is a continuation application of International Application PCT/JP2012/078255 filed on Oct. 31, 2012, and designated U.S., the entire contents of which are incorporated herein by reference.

### FIELD

The embodiments discussed herein are related to a margin test of memory.

### BACKGROUND

In memory loaded into an information processing device, signal processing is performed by a parallel transmission. Therefore, a memory controller has to communicate a plurality of signals with the memory, and preferably adjust the phase of a clock signal, a command signal, a data signal, an address signal, etc. A technique of adjusting the phase of a signal in DDR-SDRAM may be, for example, Japanese Laid-open Patent Publication No. 2010-157113.

A signal which is communicated between the memory controller and the memory may be, for example, a data strobe signal (DQS) and a data signal (DQ). The data strobe signal is a strobe signal in the following explanation.

In the above-mentioned technique for a phase adjustment, the signal processing is performed by a read, a write, etc. of data on the memory using as operation timing the time points of the rising edge and the falling edge of a strobe signal input from the memory controller. In this case, the memory controller adjusts the delay time of the strobe signal, and controls the phase of the edge as the operation timing, thereby performing the signal processing in the valid period in which the data signal in the signal processing indicates a high level or a low level. In the following explanation, the operation timing which is provided as the time of the edge of the strobe signal is referred to as operation timing of the strobe signal or simply as operation timing.

The setting period of operation timing with which the signal processing may be performed is the period of a timing margin from the margin start time obtained by adding an internal delay time and a setup time to the start time of the valid period to the margin end time obtained by subtracting a hold time from the end time of the valid period. Therefore, the memory controller adjusts the phase of the strobe signal so that the operation timing will be set within the range of the timing margin as a period in which the signal processing may be performed normally. In the following explanation, it is assumed that the internal delay time is included in the setup time.

Since the setup time and the hold time depend on the specifications and the individual differences in each unit of memory, the timing margin is different for each unit of memory. In addition, the timing margin of the memory implemented in an information processing device depends on the fluctuation of the operation environment such as the temperature and the operation voltage (simply the voltage) of the information processing device, and the operation clock of the memory during the operation of the information processing device. Therefore, a memory whose timing margin was originally short and which is subject to fluctuation by which the timing margin considerably decreases due to the fluctuation of the operation environment and due to the operation clock of the information processing device being unable to maintain the timing margin, may possibly fail to normally perform the signal processing.

In an information processing device such as a high reliability server which is requested to suppress a memory error, it is preferably to avoid loading memory which is subject to the fluctuation. Therefore, a margin test is conducted on each unit of memory before implementation in an information processing device, and only the memory which has been judged as being provided with a sufficient margin and proof against fluctuation is loaded.

In the margin test, for example, it is preferably to conduct a long-term high-load running test on each unit of memory using a special device which generates a high temperature and a high-speed clock.

### SUMMARY

According to an aspect of the embodiments of the present invention, an information processing device includes a storage unit and a processor. The storage unit which stores margin information that stores a specified margin that indicates a length for a normal operation of signal processing for a timing margin obtained by subtracting a restriction time in which the signal processing is not operating normally by setting an operation timing from a valid period in which a data signal indicates a high level or a low level, with the specified margin being associated with one or more combinations of memory information indicating one or more types of memory and environment information indicating one or more operation environments of the information processing device. The processor outputs a strobe signal that has a rising edge or a falling edge to memory implemented in the information processing device, and causing the memory to perform signal processing using at least one of the edges as an operation timing. in the process of allowing the memory to perform the signal processing, the processor changing the operation timing by changing a delay time of the strobe signal, and specifying a range of the operation timing within which the signal processing may be performed normally. The processor acquiring the specified range of the operation timing as a measured margin. The processor extracts the specified margin associated with a combination of a type of memory and an operation environment of a current information processing device from the margin information. The processor judges that the memory is not operating normally in the information processing device when the acquired measured margin is shorter than the extracted specified margin.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a block diagram of the function illustrating an embodiment of the information processing device according to a mode 1 for embodying the present invention;

FIG. 2 is a block diagram illustrating an embodiment of the information processing device;

FIG. 3 is an explanatory view of the signal processing of the information processing device;

FIG. 4 is an explanatory view of setup time and hold time;

FIG. 5 is an explanatory view of a timing margin;

FIGS. 6A and 6B are explanatory views of acquiring a measured margin;

FIGS. 7A and 7B are explanatory views of acquiring a measured margin;

FIG. 8 is a table indicating a data example of a margin table;

FIG. 9 is an explanatory view of a judgment as to whether or not implemented memory operates normally;

FIG. 10 is a sequence illustrating the process contents of a margin test according to the mode 1 for embodying the present invention;

FIG. 11 is a sequence illustrating the process contents of a margin test according to the mode 1 for embodying the present invention;

FIG. 12 is a sequence illustrating the process contents of a margin test according to the mode 1 for embodying the present invention;

FIG. 13A and 13B are explanatory views of the difference in measured margin between startup and operation;

FIG. 14 is an explanatory view of the difference in position of reference time between startup and operation;

FIG. 15 is a block diagram of the function illustrating an embodiment of the information processing device according to a mode 2 for embodying the present invention;

FIGS. 16A and 16B are tables indicating a data example of a correction table;

FIG. 17 is a sequence illustrating the process contents of a margin test according to the mode 2 for embodying the present invention; and

FIG. 18 is a sequence illustrating the process contents of a margin test according to the mode 2 for embodying the present invention.

### DESCRIPTION OF EMBODIMENTS

### Mode 1 for Embodying the Present Invention

The information processing device according to the mode 1 for embodying the present invention is described below.

The information processing device stores in a margin table a specified margin as the length of a timing margin for normal operation of signal processing which has been obtained by an experiment, along with the specified margin associated with each combination of an approximation of memory and environment information about the information processing device.

The information processing device is activated after replacement of memory in implementing memory in production and maintaining the memory, and performs signal processing while shifting the operation timing of a strobe signal. Then, the information processing device acquires a measured margin as a measured timing margin of implemented memory by detecting the operation timing in which the signal processing is performed normally.

The information processing device further acquires the specifications of the implemented memory from the SPD (serial presence detect) on the implemented memory which has stored various types of information of the implemented memory. The information processing device also acquires the temperature and the voltage of the information processing device from the temperature sensor and the voltage sensor of the information processing device. Then, the information processing device extracts the specified margin corresponding to the acquired specifications of the memory and the temperature and the voltage of the information processing device from the margin table.

The information processing device judges that the implemented memory is not operating normally in the information processing device when the acquired measured margin is smaller than the extracted specified margin.

Thus, since the information processing device detects the memory which has a short timing margin and is subject to fluctuation without conducting a long-term and high-load running test using a special device, the information processing device may efficiently conduct a margin test on the implemented memory.

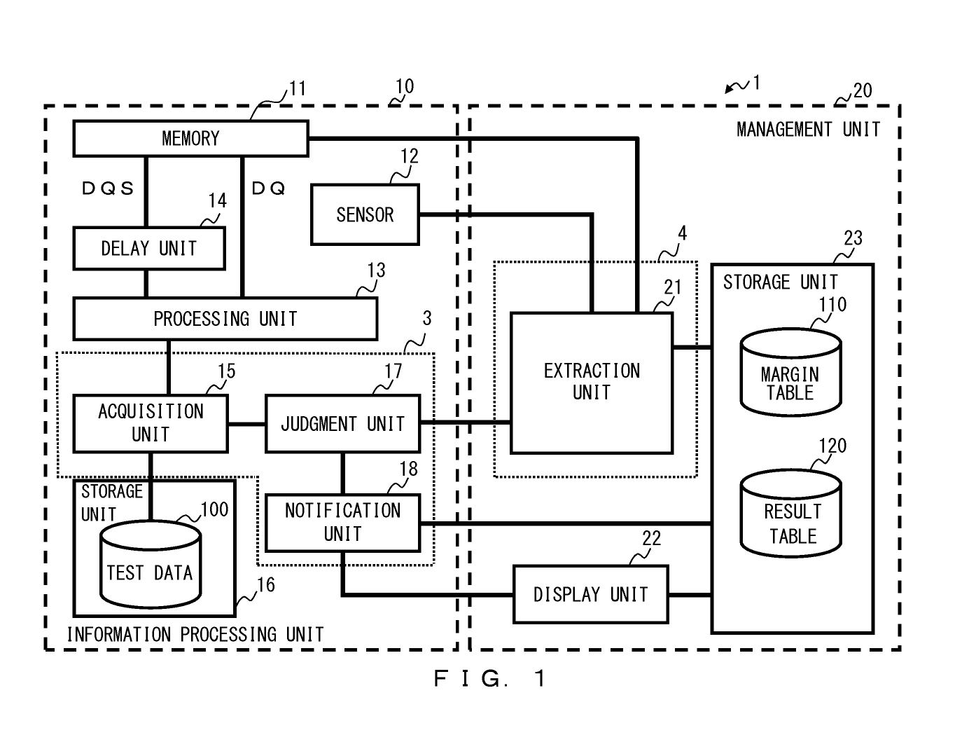

FIG. 1 is a block diagram of the function illustrating an embodiment of the information processing device.

In FIG. 1, an information processing device 1 includes an information processing unit 10 and a management unit 20.

The information processing unit 10 includes an information control unit 3, memory 11, a sensor 12, a processing unit 13, a delay unit 14, and a storage unit 16.

The information control unit 3 controls the entire information processing unit 10. The information control unit 3 includes an acquisition unit 15, a judgment unit 17, and a notification unit 18.

The memory 11 performs signal processing such as a read of data stored in the memory 11 and a write of data included in an input data signal using a rising edge and a falling edge of a strobe signal input from the processing unit 13 as operation timing.

The sensor 12 acquires the temperature and the voltage of the information processing device 1. Then, the sensor 12 outputs the acquired temperature and voltage to an extraction unit 21.

The processing unit 13 is connected to the memory 11 through a data bus (DQ) through which data is communicated and a strobe bus (DQS) through which a strobe signal is transmitted. Then, the processing unit 13 performs the signal processing such as a read and a write of data to the memory 11 with the operation timing by transmitting a data signal and a strobe signal to the memory 11.

The delay unit 14 changes the delay time of the strobe signal output from the processing unit 13 and changes the timing of edges, thereby adjusting the operation timing of the strobe signal.

The acquisition unit 15 controls the delay unit 14 and changes the delay time of the strobe signal, thereby stepwise changing the operation timing. Then, the acquisition unit 15 controls the processing unit 13, thereby allowing the process to perform the signal processing each time the operation timing is changed. Then, the acquisition unit 15 specifies the range of the operation timing within which the signal processing may be performed normally, and acquires the specified range of the operation timing as a measured margin.

The acquisition unit 15 sets a particular reference time between the margin start time which is reached after the passage of the setup time from the start time of the valid period of a data signal and the margin end time which is reached at the hold time from the end time of the valid period of the data signal. The setup time is the time in which data to be input in advance is held before the operation timing of the strobe signal so that the data signal is input from the processing unit 13 to the memory 11. The hold time is the time in which data is held after the operation timing of the strobe signal so that the memory 11 may receive data without fail. The setup time includes the internal delay time of a chipset.

The storage unit 16 stores test data 100 (particular data). The test data 100 is used in judging whether or not the signal processing has been performed normally on the memory 11. As an example of using the test data 100, the processing unit 13 writes the test data 100 at a particular address of the memory 11, and reads the data at the particular address in the state in which the operation timing is held. The acquisition unit 15 compares the read data with the test data 100 stored in the storage unit 16, and judges that the signal processing has been performed normally in the memory 11 when the comparison indicates a matching result. The acquisition unit 15 makes the judgment while adjusting the delay time of the strobe signal and changing the operation timing, thereby acquiring a measured margin.

The judgment unit 17 judges that implemented memory is not operating normally in the information processing device when the measured margin acquired by the acquisition unit 15 is shorter than the specified margin corresponding to the combination of the type of implemented memory and the current operation environment of the information processing device.

The notification unit 18 transmits the judgment result by the judgment unit 17 to the management unit 20.

The management unit 20 includes a management control unit 4, a display unit 22, and a storage unit 23.

The management control unit 4 controls the entire management unit 20. The management control unit 4 includes the extraction unit 21.

The extraction unit 21 extracts a specified margin corresponding to the combination of the type of implemented memory and the current operation environment of the information processing device 1 from a margin table 110 stored in the storage unit 23.

The display unit 22 displays the judgment result by the judgment unit 17 which has been reported by the notification unit 18 or the judgment result by the judgment unit 17 stored in a result table 120 held in the storage unit 23 so that a user may visually recognize the judgment result. Thus, the user may recognize whether or not the memory 11, which is implemented in the information processing device 1 and on which the margin test has been conducted, may operate normally. Therefore, the user may omit the memory 11 which is not operating normally in the information processing device 1 from among the memory units 11 implemented in the information processing device 1.

The storage unit 23 stores the margin table 110 (margin information) and the result table 120.

The margin table 110 stores a specified margin with the specified margin associated with one or more combinations of the memory information indicating one or more types of memory and the environment information indicating one or more operation environments of an information processing device.

The result table 120 stores the judgment result by the judgment unit 17 which has been reported by the notification unit 18. In practice, the judgment result as to whether or not each unit of memory 11, which is implemented in the information processing device 1 and on which the margin test has been conducted, operates normally in the information processing device 1, and the measured margin, the specifications, the operation environment at the test, etc. are stored. Thus, the user refers to the result table 120 using the display unit 22 etc., and judges whether or not each unit of memory 11 is to be implemented in the information processing device 1. Furthermore, the user compares the measured margins of the units of memory 11 stored in the result table 120, thereby comparing the relative performances of the units of memory 11.

The storage unit 16, the test data 100 stored in the storage unit 23, the margin table 110, and the result table 120 may be stored after being appropriately exchanged.

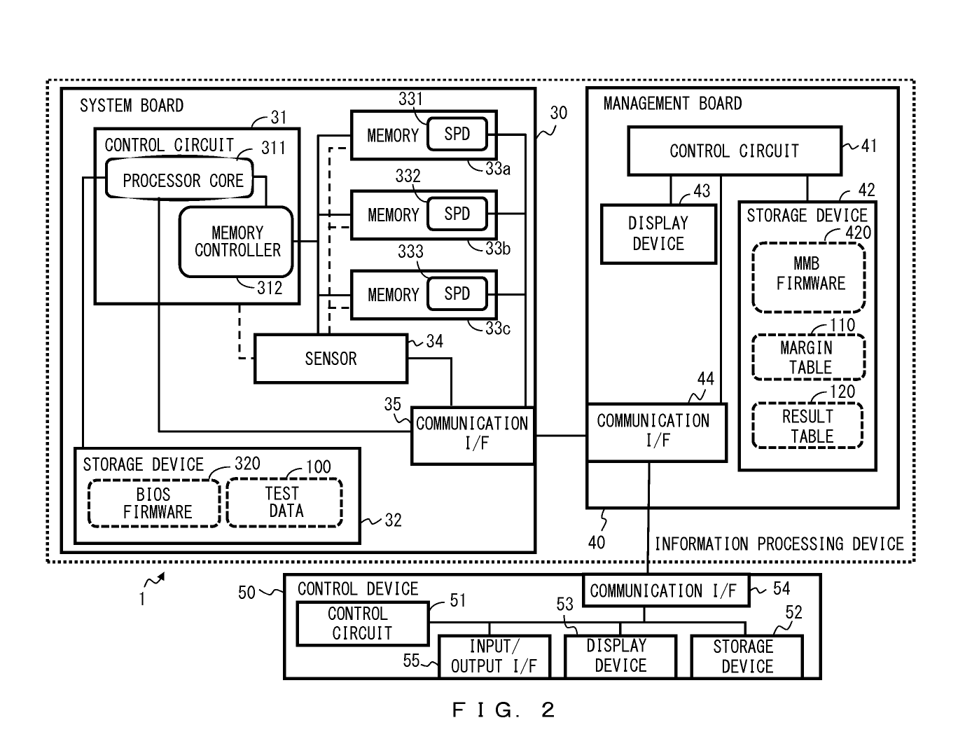

FIG. 2 is a block diagram illustrating an embodiment of the information processing device.

In FIG. 2, the information processing device 1 includes a system board 30 and a management board 40.

The system board 30 includes a control circuit 31, a storage device 32, memory 33a through 33c, a sensor 34, and a communication interface 35 (communication I/F). Then, in FIG. 1, the system board 30 functions as the information processing unit 10.

The control circuit 31 includes a processor core 311 and a memory controller 312. Then, the control circuit 31 controls the entire system board 30. The control circuit 31 is, for example, a processor such as a CPU, a multi-core CPU, an FPGA (field programmable gate array), a PLD (programmable logic device), etc. In FIG. 1, the processor core 311 functions as the information control unit 3. In FIG. 1, the memory controller 312 functions as the processing unit 13 and the delay unit 14.

The storage device 32 stores BIOS firmware 320 and test data 100. The storage device 32 is, for example, memory such as ROM (read only memory), RAM (random access memory), etc. and a non-transitory computer-readable recording medium such as an HD (hard disk) etc. The BIOS firmware 320 allows the processor core 311 to function as the information control unit 3 illustrated in FIG. 1 by being executed by the processor core 311 at a start time of the information processing device 1.

The memories 33a through 33c are used as the main storage devices of the information processing device 1, and data is read and written by control of the memory controller 312. The memories 33a through 33c are, for example, DDR-SDRAM (double data rate synchronous dynamic random access memory) etc. The memories 33a through 33c are also non-transitory computer-readable recording media such as DIMMs (dual inline memory modules) etc. The memory 11 in FIG. 1 is not limited to DDR-SDRAM, but may be memory on which signal processing such as a read or a write of data is performed using the edge of a strobe signal input from the processing unit 13 as operation timing.

The memories 33a through 33c also include SPD 331 through 333 to which the specifications of each memory unit are written. The memories 33a through 33c function as the memory 11 illustrated in FIG. 1.

The sensor 34 is, for example, a temperature sensor such as a thermistor etc. or a voltmeter. Then, the sensor 34 functions as the sensor 12 illustrated in FIG. 1.

The communication interface 35 connects for communication the system board 30 and the management board 40 through a power line communication, a LAN cable, and a wireless communication.

The management board 40 includes a control circuit 41, a storage device 42, a display device 43, and a communication interface 44 (communication I/F). In FIG. 1, the management board 40 functions as the management unit 20.

The control circuit 41 is, for example, a processor such as a CPU, a multi-core CPU, an FPGA (field programmable gate array), a PLD (programmable logic device), etc. In FIG. 1, the control circuit 41 functions as the management control unit 4.

The storage device 42 stores MMB firmware 420, the margin table 110, and the result table 120. The storage device 32 is, for example, memory such as ROM, RAM, etc. and a non-transitory computer-readable recording medium such as an HD etc. The MMB firmware 420 allows the control circuit 41 to function as the management control unit 4 illustrated in FIG. 1 by being executed by the control circuit 41 at startup of the information processing device 1.

The display device 43 is, for example, a CRT (cathode ray tube), an LCD (liquid crystal display), a PDP (plasma display panel), an GELD (organic electroluminescence display), etc. Then, in FIG. 1, the display device 43 functions as the display unit 22.

The communication interface 44 connects for communication the system board 30 and the management board 40 through a power line communication, a LAN cable, and a wireless communication. The communication interface 44 also connects for communication the system board 30 and a control device 50 described later through a power line communication, a LAN cable, and a wireless communication.

An example of the information processing device 1 including the system board 30 and the management board 40 is described above, but the information processing device 1 may be configured by one board. That is, the information processing device 1 may have any appropriate and selected configuration as long as the configuration is able to realize the function illustrated in FIG. 1.

The control device 50 in FIG. 2 is a computer device for control of the information processing device 1, and includes a control circuit 51, a storage device 52, a display device 53, a communication interface 54 (communication I/F), and an input/output interface (input/output I/F) 55.

The configuration of the control device 50 is the same as the configuration of a well-known computer device. The control device 50 is used by a user in inputting control information such as a startup request of the information processing device 1 etc. through an input terminal connected to the input/output interface 55. Furthermore, the control device 50 refers to the result table 120 through the communication interface 54 with the operation of a user, and displays the judgment result of the judgment unit 17 on the display device 53. The display device 53 also displays the judgment result of the judgment unit 17 input through the communication interface 44.

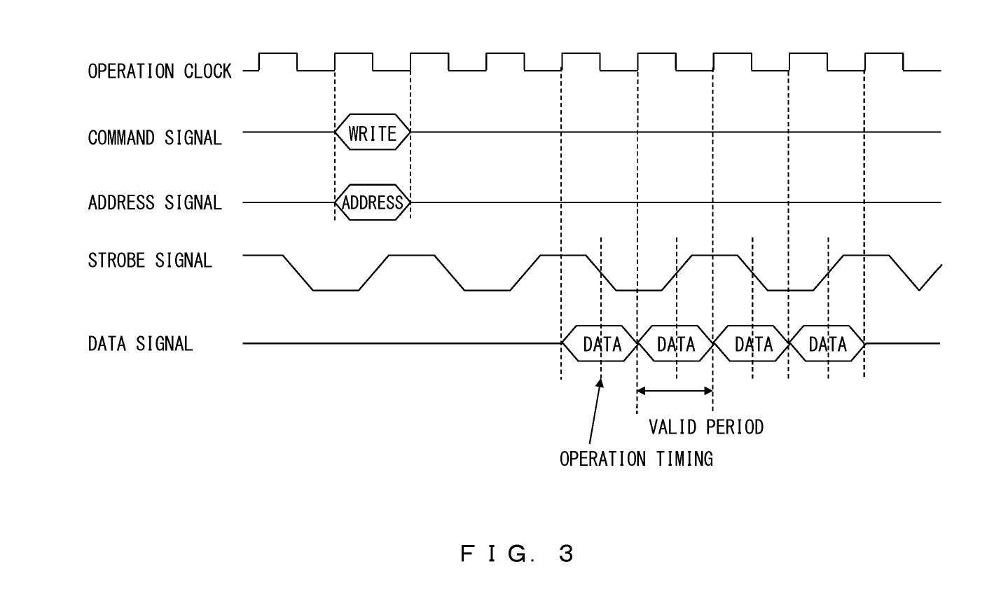

FIG. 3 is an explanatory view of the signal processing of an information processing device.

In the following explanation, an example of the acquisition unit 15 requesting a process of writing data on the memory 11 is explained. The operation clock in FIG. 3 is an operation clock of the processing unit 13. A command signal specifies the type of signal processing to be performed on the memory 11. An address signal specifies an address from the processing unit 13 to the memory 11. When signal processing other than the process of writing data is performed, the type of command signal may be appropriately changed.

First, the acquisition unit 15 requests that the processing unit 13 write data to the memory 11. Then, the processing unit 13 outputs a write request and an address signal for specification of the address of the storage area of the memory 11 to the memory 11 in synchronization with the rising of values of an operation clock.

When the write request and the address signal are input, the memory 11 receives data from the data signal with the operation timing of the strobe signal input from the processing unit 13. Then, the memory 11 stores the received data at the address specified by the input address signal.

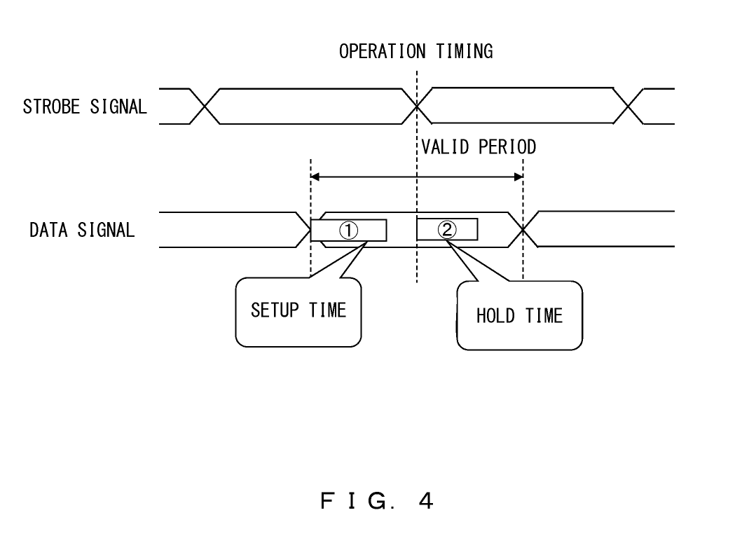

FIG. 4 is an explanatory view of setup time and hold time.

As illustrated in FIG. 3, the signal processing on the memory 11 is performed with the operation timing of the strobe signal input from the processing unit 13. Then, the operation timing is set by considering the restriction time of the setup time and the hold time. Described below are the setup time and the hold time.

The setup time is the time in which the processing unit 13 holds a data signal in the same state so as to perform normal signal processing after a valid period is started and a data signal reaches a high level or a low level. Therefore, the processing unit 13 sets operation timing as the time point after the passage of the setup time from the start time of the valid period. In FIGS. 4 through 7, 9, and 13, the setup time is indicated by 1.

The hold time is the time in which the signal processing may be terminated normally by the processing unit 13 holding the data signal in the same state from the operation timing of the strobe signal. Therefore, the processing unit 13 sets the operation timing at the time point where the valid period continues from the operation timing of the strobe signal to the passage of the hold time. In FIGS. 4 through 7, 9, and 13, the hold time is indicated by 2.

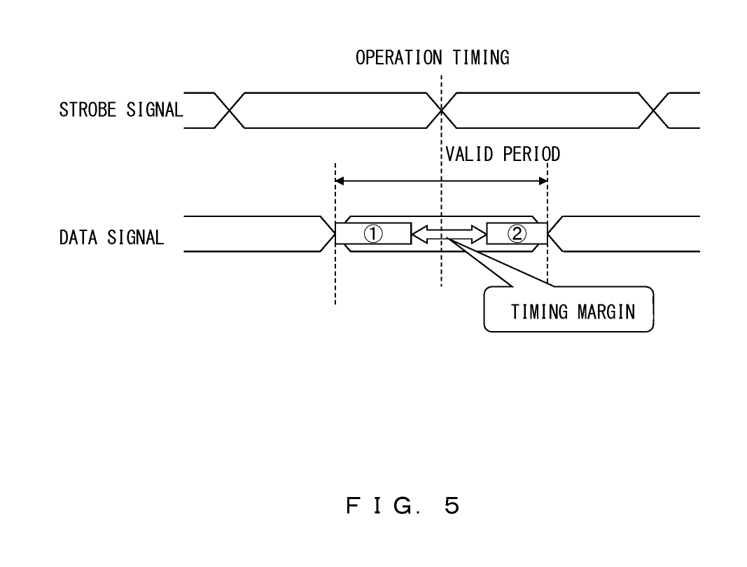

FIG. 5 is an explanatory view of a timing margin.

As illustrated in FIG. 4, the processing unit 13 sets the operation timing of the strobe signal by considering the restriction time of the setup time and the hold time.

The timing margin indicates the period in which normal signal processing may be performed when operation timing is set in the valid period of a data signal.

Since signal processing is not performed normally until the margin start time at which the setup time has passed from the start time of the valid time of a data signal, the operation timing may be set at and after the margin start time. Since a time not less than the hold time may pass before the end time of the valid period of a data signal from the operation timing, the operation timing may be set at or before the margin end time obtained by subtracting the hold time from the end time of the valid time.

Therefore, the timing margin is the period indicated by the left and right arrows illustrated in FIG. 5.

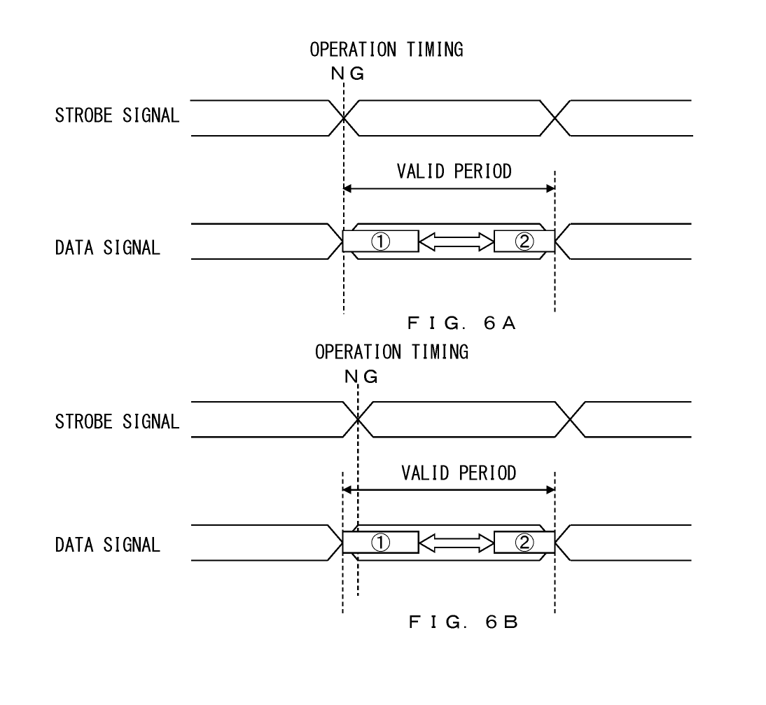

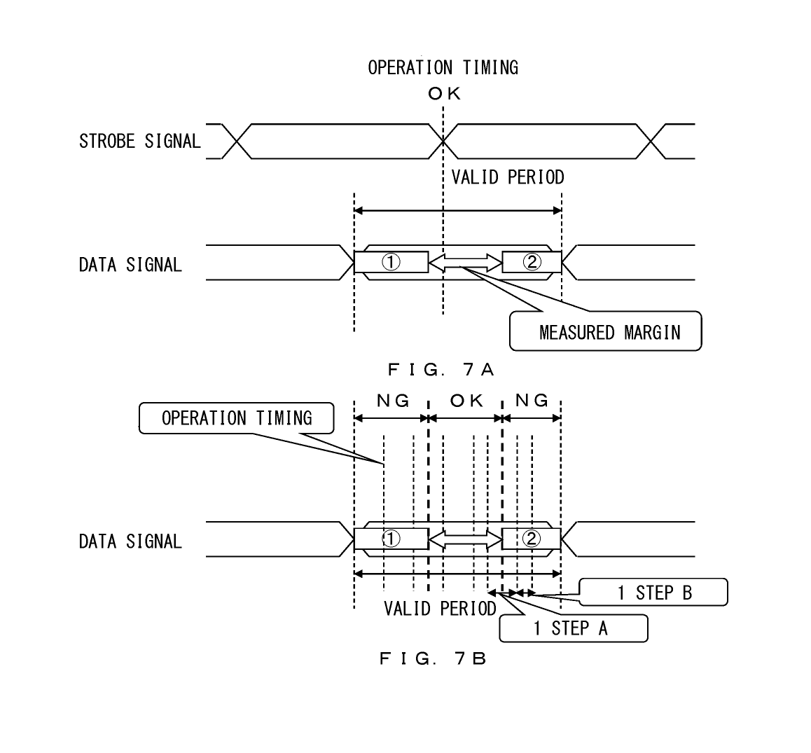

FIGS. 6 and 7 are explanatory views of acquiring a measured margin.

The acquisition unit 15 acquires a measured margin when the information processing device 1 is activated. The acquisition of the measured margin of the acquisition unit 15 is described below with reference to FIGS. 6 and 7.

When the information processing device 1 is activated, the acquisition unit 15 controls the delay unit 14 so as to change the delay time of a strobe signal, thereby delaying the time of the edge of the strobe signal, and sets the operation timing at the start time of a valid period. Then, the acquisition unit 15 controls the processing unit 13 to allow the memory 11 to perform the signal processing, and judges whether or not the signal processing has been performed normally. In this case, as illustrated in FIG. 6A, since the operation timing is not set in the timing margin, the acquisition unit 15 is not performed normally (NG).

When the acquisition unit 15 finishes the judgment as to whether or not the signal processing has been performed normally, it further controls the delay unit 14 so as to change the delay time of the strobe signal, thereby shifting the operation timing by 1 step toward the end time of the valid period. Then, the acquisition unit 15 controls the processing unit 13 to allow the memory 11 to perform the signal processing, thereby judging whether or not the signal processing has been performed normally. In this case, as illustrated in FIG. 6B, the operation timing is not set in the timing margin. Therefore, the acquisition unit 15 judges that the signal processing has not been performed normally (NG). A step indicates a unit time of delay in operation timing appropriately set by a user.

The acquisition unit 15 performs the above-mentioned processing from the start time to the end time of the valid period while shifting the operation timing step by step, and extracts the period in which the signal processing has been performed normally. The normal signal processing is judged (OK) for the period in which the operation timing is set in the timing margin.

The acquisition unit 15 acquires the extracted period as the measured margin, which is a measured value of the timing margin. The processing unit 13 sets the operation timing as indicated by the broken line illustrated in FIG. 7B, and judges whether or not the signal processing has been performed normally, thereby extracting a measured margin. The acquisition unit 15 may control the processing unit 13 and repeatedly judges whether or not the signal processing has been performed normally while gradually shortening the unit time of one step at the boundary between the OK timing and the NG timing of the detected operation timing. Thus, the acquisition unit 15 may more correctly acquire a measured margin. For example, in FIG. 7B, the 1 step A indicates a delay unit time of the operation timing initially set by the acquisition unit 15. In FIG. 7B, the 1 step B indicates a delay unit time of the operation timing changed by the acquisition unit 15. The acquisition unit 15 controls the processing unit 13 and detects the operation timing using the 1 step B at the boundary between the OK timing and the NG timing of the detected operation timing using the 1 step A, thereby more correctly acquiring a measured margin.

Described below is an example of a method of judging whether or not signal processing has been correctly performed.

The acquisition unit 15 controls the processing unit 13 to write, for example, the test data 100 stored in the storage unit 16 to the memory 11 with an address specified. Furthermore, the acquisition unit 15 controls the processing unit 13 to read data from the address at which the test data 100 has been written while holding the state of the operation timing with which the test data 100 is written to the memory 11. The acquisition unit 15 compares the read test data 100 with the read data, and when the data indicates a matching result, the acquisition unit 15 judges that the signal processing has been performed normally. If the acquisition unit 15 compares the read test data 100 with the read data, and the data indicates a non-matching result, then the acquisition unit 15 judges that the signal processing has not been performed normally. It may be judged whether or not the signal processing has been performed normally in any other appropriately selected method for judging whether or not the signal processing has been performed normally.

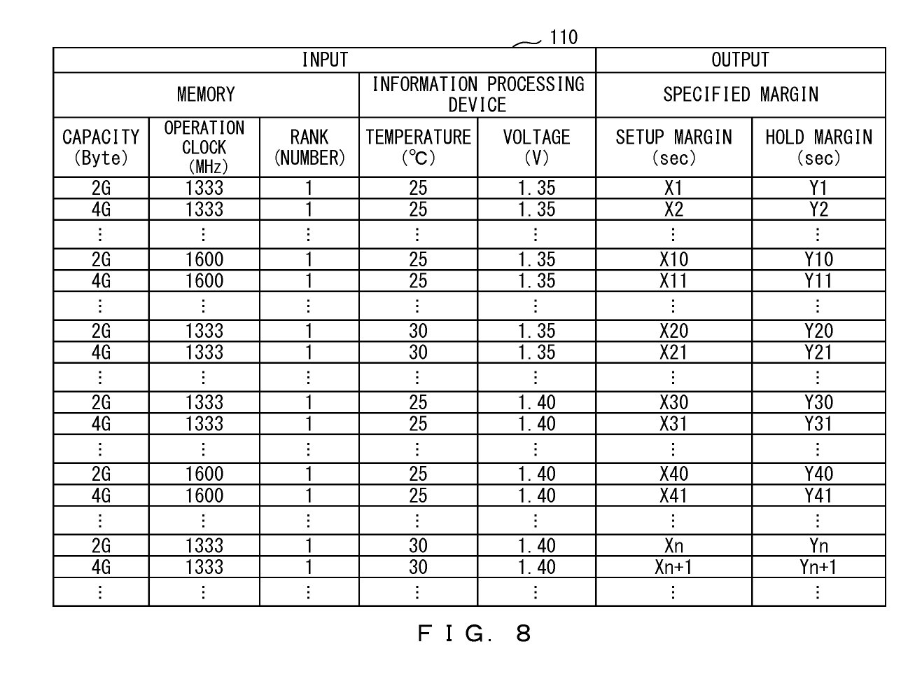

FIG. 8 is a table indicating a data example of a margin table.

As illustrated in FIG. 8, the margin table 110 stores as memory information indicating the type of memory the specifications of a plurality of memory units such as the capacity of memory, an operation clock, a rank, etc. Furthermore, the margin table 110 stores in association with the memory information a plurality of operation environments such as a temperature, a drive voltage, etc. as the environment information about the information processing device 1. The memory information and the environment information are hereafter referred to as input information.

In addition, the margin table 110 stores a setup margin and a hold margin as specified margins in association with the input information. In the following explanation, it is assumed that a specified margin is a margin indicating the period obtained by adding up the setup margin and the hold margin.

The setup margin is a margin for specification of a length for the time between the reference time and the margin start time for the normal operation of signal processing when the reference time is set between the margin start time and the margin end time.

The hold margin is a margin for specification of a length for the time between the reference time and the margin end time for the normal operation of the signal processing.

That is, when the time between the reference time and the margin start time is longer than the setup margin and the time between the reference time and the margin end time is longer than the hold margin, the information control unit 3 may set an operation timing with which the signal processing may be performed normally.

The setup margin, the hold margin, and the reference time are determined in the designing process of a product. For the setup margin and the hold margin, an empirical value acquired by practically verifying the entirety of the information acquired from memory and the sensor 12 of the information processing device 1 in the designing process is set using the set reference time as a reference. Therefore, in different information processing devices 1, different setup margins and hold margins are set.

The reference time is set based on, for example, the agreement that it is an intermediate time having equal time intervals from the margin start time and the margin end time when the acquisition unit 15 acquires a measured timing margin, and is stored in the storage unit 16.

A setup margin and a hold margin may be stored in the margin table 110 as one specified margin obtained by adding up the setup margin and the hold margin. In this case, a reference time is not set.

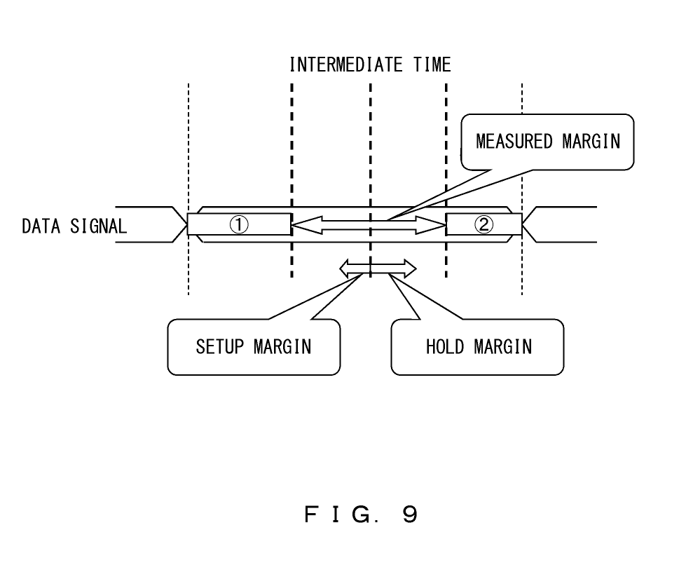

FIG. 9 is an explanatory view of a judgment as to whether or not implemented memory operates normally.

The right and left arrows in the data signal illustrated in FIG. 9 indicate a measured margin.

The judgment unit 17 obtains an intermediate time by, for example, referring to the storage unit 16, adding a margin end time to a margin start time, and dividing the sum by 2 when a reference time is set as an intermediate time.

The extraction unit 21 extracts from the margin table 110 the type of the memory 11 acquired from the memory 11, the setup margin corresponding to the operation environment of the information processing device 1 input from the sensor 12, and a hold margin, and transmits them to the judgment unit 17.

The acquisition unit 15 controls the processing unit 13, acquires a measured margin of the memory 11, and inputs it to the judgment unit 17.

The judgment unit 17 judges that the memory 11 operates normally in the information processing device 1 when, as illustrated in FIG. 9, the time obtained by subtracting a setup margin from an intermediate time is included in a measured margin, and the time obtained by adding a hold margin to the intermediate time is included in the measured margin. That is, the judgment unit 17 judges that the memory 11 is not subject to a fluctuation and has a sufficient margin.

The judgment unit 17 judges that the implemented memory is not operating normally in the information processing device 1 when the time obtained by subtracting a setup margin from an intermediate time is not included in a measured margin, or when the time obtained by adding a hold margin to an intermediate time is not included in a measured margin. That is, the judgment unit 17 judges that the memory 11 is subject to a fluctuation.

In this case, the processing unit 13 may set operation timing at an intermediate time when the memory 11 is used. The processing unit 13 may also set the boundary between a setup margin and a hold margin as an operation timing, and set the operation timing so that the setup margin and the hold margin are included in a measured margin. Furthermore, the processing unit 13 may set the center of the setup margin and the hold margin as an operation timing, and set the operation timing so that the setup margin and the hold margin are included in a measured margin.

When a specified margin is set as one margin obtained by adding up a setup margin and a hold margin, the judgment unit 17 judges that the implemented memory operates normally in the information processing device 1 when a specified margin is shorter than a measured margin.

In this case, the processing unit 13 may set the center of a specified margin as an operation timing when the memory 11 is used, and set the operation timing so that the specified margin is included in a measured margin.

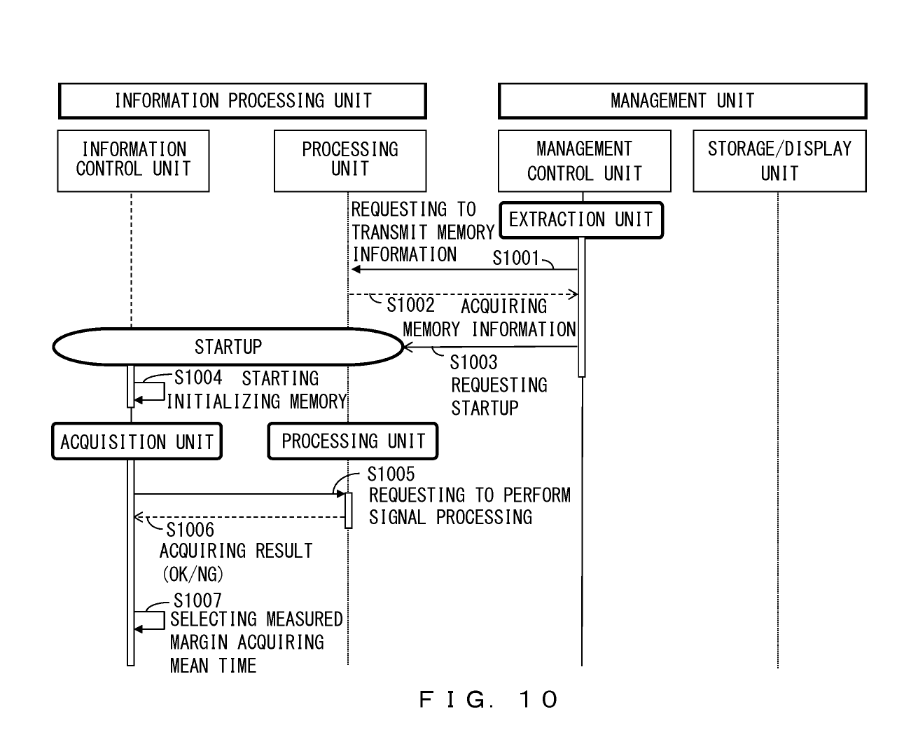

FIGS. 10 through 12 illustrate a sequence illustrating the process contents of a margin test according to the mode 1 for embodying the present invention.

In the following explanation, it is assumed that the mean time of a measured margin is set as a reference time.

In FIG. 10, when the information processing device 1 is activated, the extraction unit 21 requests that the memory 11 transmit memory information (S1001). Then, the memory 11 transmits the specifications stored in the SPD as memory information to the extraction unit 21. Thus, the extraction unit 21 acquires the memory information (S1002).

The extraction unit 21 of the management control unit 4 requests that the information processing unit 10 perform activation (S1003). Then, the information processing unit 10 is activated and starts the initiating process on the memory (S1004).

Next, the acquisition unit 15 requests that the processing unit 13 judge whether or not the signal processing is performed normally at a corresponding time in each step in a valid period of a data signal (S1005).

The processing unit 13 controls the delay unit 14 and adjusts the delay time of a strobe signal, thereby performing the signal processing in a valid period while changing the operation timing step by step. Then, the processing unit 13 notifies the acquisition unit 15 as to whether or not the signal processing has been performed normally step by step. Thus, the acquisition unit 15 acquires the result of the possibility of the execution of the signal processing at a corresponding time for each step in a valid period (S1006).

The acquisition unit 15 acquires a measured margin from the result acquired from the processing unit 13 in regard to whether or not the signal processing may be performed in each step, and obtains the mean time (S1007).

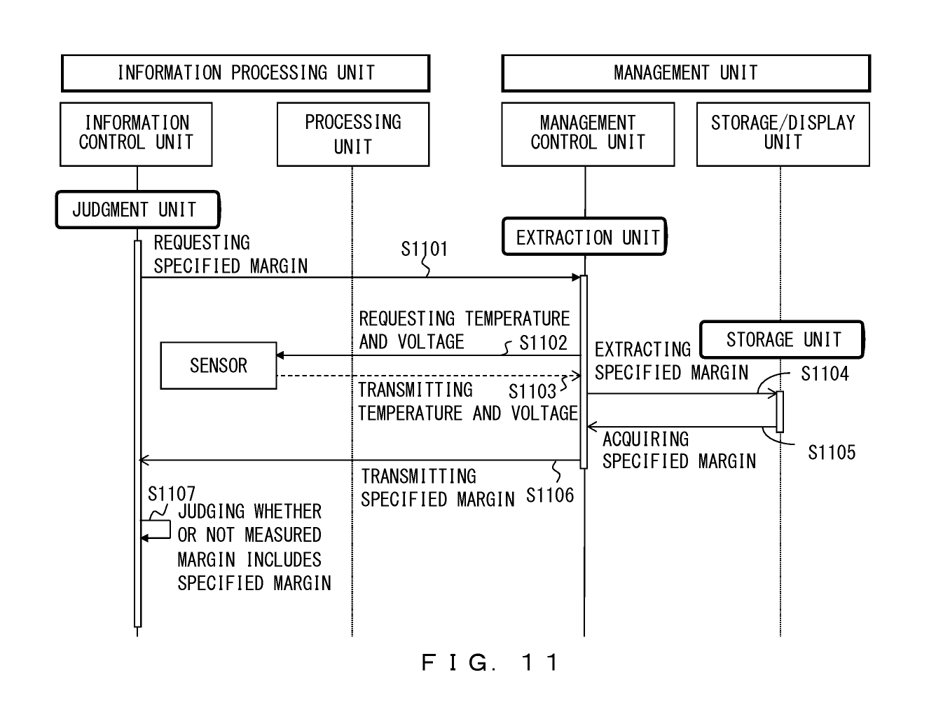

As illustrated in FIG. 11, the judgment unit 17 requests that the extraction unit 21 extract the specified margin in the current operation environment of the information processing device 1 of the implemented memory 11 (S1101). Then, the extraction unit 21 requests that the sensor 34 send the temperature of the information processing device 1 and the measured value of the voltage (S1102). The sensor 34 transmits the temperature and the measured value of the voltage to the extraction unit 21 (S1103). Thus, the extraction unit 21 acquires the temperature and the voltage of the information processing device 1 as the environment information.

The extraction unit 21 extracts the memory information acquired in 51002 and the specified margin corresponding to the environment information acquired in 51103 from the margin table 110 (S1104). Then, the extraction unit 21 acquires the extracted specified margin from the margin table 110 (S1105).

Furthermore, the extraction unit 21 transmits the acquired specified margin to the judgment unit 17 (S1106). Thus, the judgment unit 17 acquires the type of the implemented memory 11 and the specified margin corresponding to the operation environment of the information processing device 1.

The judgment unit 17 judges whether or not the measured margin acquired in S1007 includes the specified margin (S1107). The judging method in S1107 uses the method explained with reference to FIG. 9.

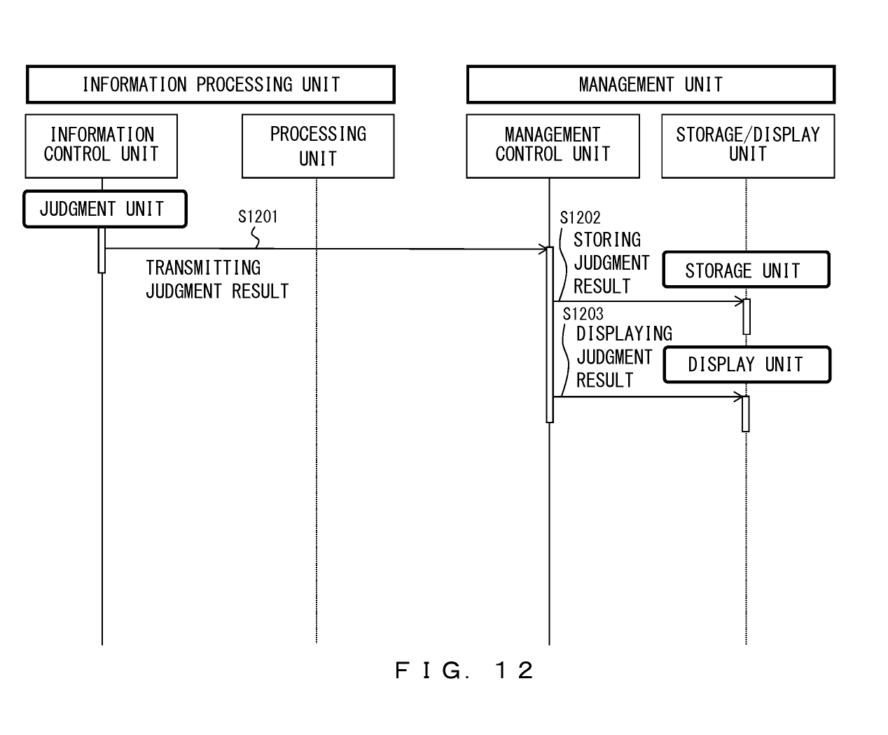

In FIG. 12, the judgment unit 17 transmits the judgment result in S1107 to the control circuit 41 (S1201).

Then, the control circuit 41 stores the judgment result in S1107 in the storage unit 23 (S1202). Furthermore, the control circuit 41 transmits the display request for the judgment result in S1107 to the display unit 22. Then, the display unit 22 displays the judgment result in S1107 (S1203).

As described above, the information processing device 1 according to the mode 1 for embodying the present invention acquires a measured margin at startup when memory is replaced in implementing and maintaining of memory in a manufacturing process. When the acquired measured margin is shorter than the extracted specified margin, the information processing device 1 judges that the memory implemented in the information processing device is not operating normally in the information processing device.

Thus, since the information processing device detects the memory which has a short timing margin and is subject to fluctuation without conducting a long-term and high-load running test using a special device, the information processing device may efficiently conduct a margin test on the implemented memory.

In the mode 1 for embodying the present invention, it is judged whether or not the setup margin and the hold margin are included in the measured margin based on the reference time. Thus, the information processing device 1 judges whether or not the memory 11 has a sufficient margin. If operation timing is set at the reference time when it is judged that the memory 11 has a sufficient margin, then the setup margin and the hold margin are included in the measured margin. Therefore, in the information processing device 1, the operation timing of the signal processing in the memory 11 may be set as the reference time.

### Mode 2 for Embodying the Present Invention

Described below is the information processing device according to the mode 2 for embodying the present invention.

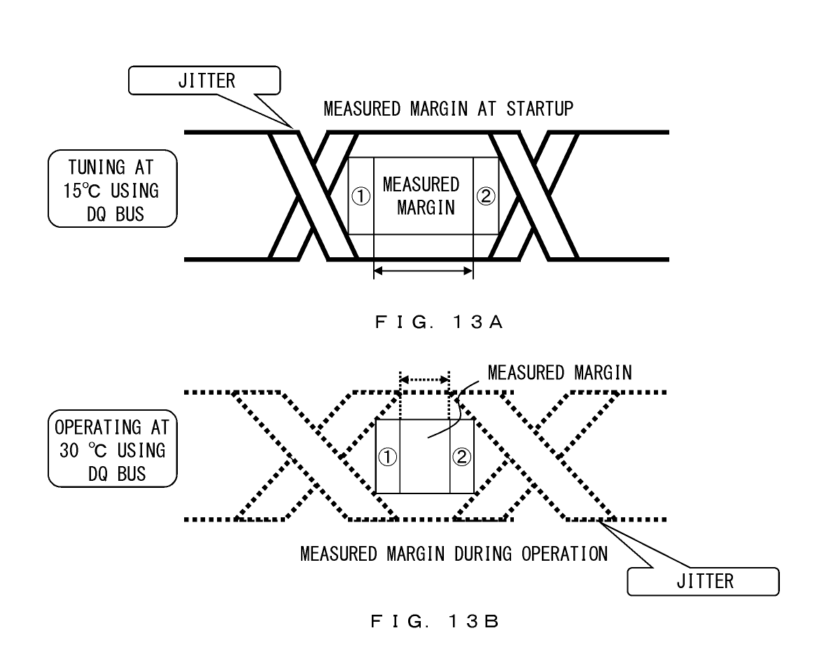

FIGS. 13A and 13B are an explanatory views of the difference in measured margin between startup and operation.

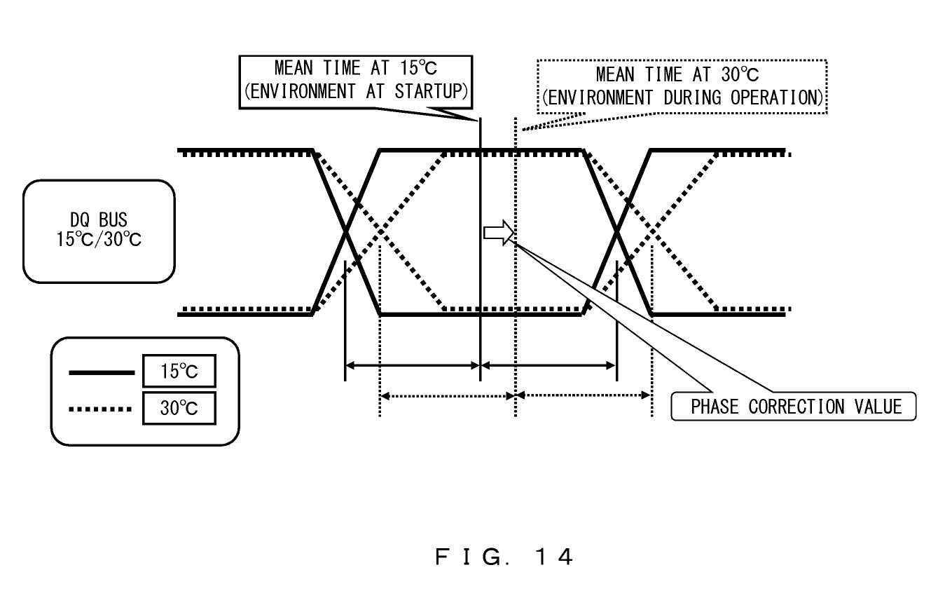

FIG. 14 is an explanatory view of the difference in position of reference time between startup and operation.

The information processing device 1 according to the mode 1 for embodying the present invention judges whether or not the memory performs normally the signal processing under the temperature condition at startup. However, when the operation of the information processing device 1 is started, the temperature may rise from the startup. Then, the measured margin of the information processing device 1 during operation may be different from the measured margin at startup.

As illustrated in FIGS. 13A and 13B, as the temperature of the information processing device 1 rises, the rising time and the falling time of a data signal may be longer. In addition, as the temperature of the information processing device 1 rises, the jitter at the rising and the falling of the data signal may be larger. With these influences, the measured margin at the temperature of 30° C. during operation of the information processing device 1 may be shorter than the measured margin at the temperature of 15° C. at startup of the information processing device 1.

As illustrated in FIG. 14, since the rising time and the falling time of the data signal become longer when the temperature of the information processing device 1 rises, the reference time of the measured margin may be shifted with the shift of the mean time of the valid period of the data signal. For example, if the mean time of the valid period of the data signal is reference time in FIG. 14, the mean time of the valid period of the data signal is shifted by the rising of the temperature, and the reference time is also shifted.

As described above, in the memory in which it has been judged that the signal processing may be performed normally under the temperature condition at startup, the signal processing may be unable to be performed normally under the temperature condition during operation if a data signal is changed.

With the above-mentioned problems, in the mode 2 for embodying the present invention, it is judged whether or not the implemented memory 11 may be performed normally using the relative relationship between the temperature when a margin test is conducted and the estimated temperature during operation by estimating the temperature of an information processing device 2 during operation.

Furthermore, in the mode 2 for embodying the present invention, the reference time is also corrected using the relative relationship between the temperature when a margin test is conducted and an estimated temperature during operation. Then, in the mode 2 for embodying the present invention, the setup margin and the hold margin after the correction may be included in the measured margin by setting the operation timing at the reference time.

Described below is the information processing device 2 according to the mode 2 for embodying the present invention.

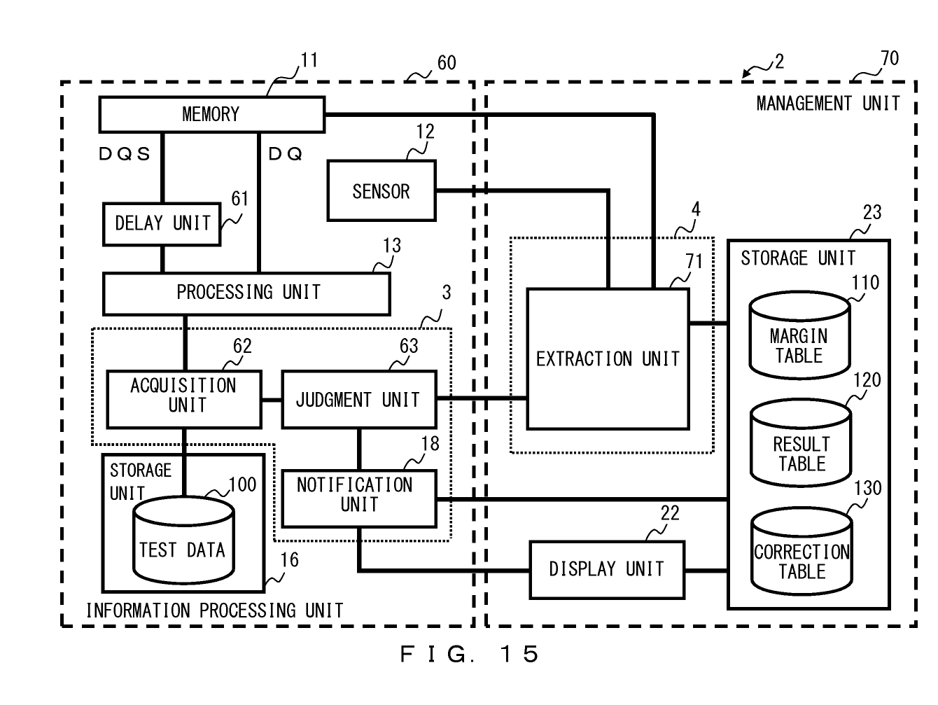

FIG. 15 is a block diagram of the function illustrating an embodiment of the information processing device according to the mode 2 for embodying the present invention.

In the mode 2 for embodying the present invention, a portion of the functions are added to the delay unit 14, the acquisition unit 15, the judgment unit 17, and the extraction unit 21 of the mode 1 for embodying the present invention, and function respectively as a delay unit 61, an acquisition unit 62, a judgment unit 63, and an extraction unit 71. In the mode 2 for embodying the present invention, a correction table 130 is stored in the storage unit 23.

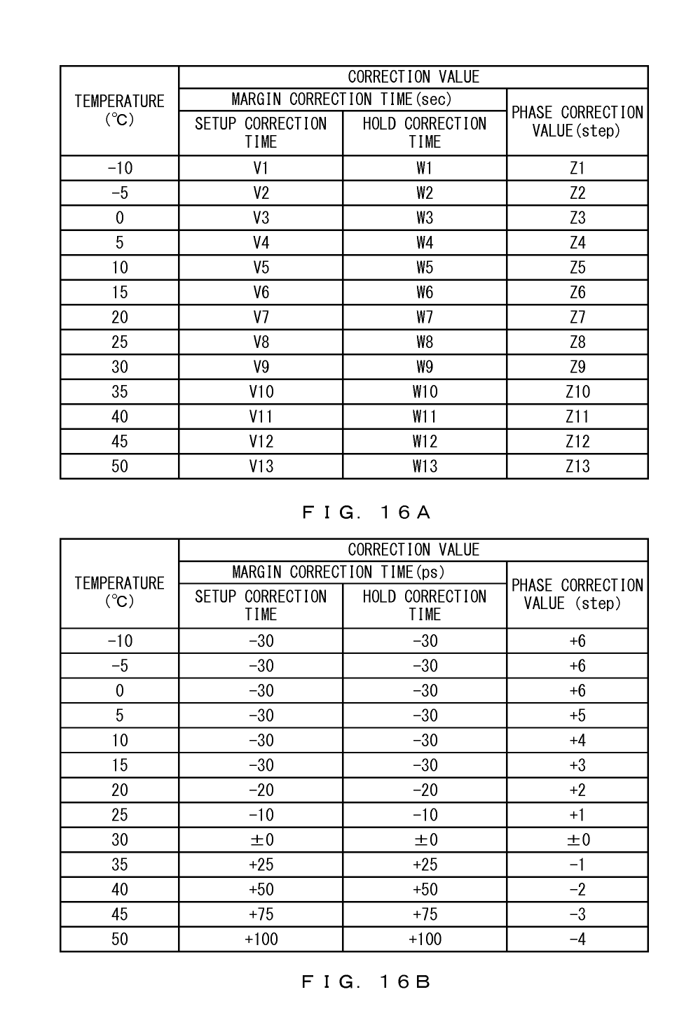

FIGS. 16A and 16B are tables including a data example of a correction table.

The correction table 130 stores margin correction time as margin correction information as illustrated in FIG. 16A. The correction table 130 also stores a phase correction value as phase correction information. The margin correction information includes setup correction time as setup correction information, and hold correction time as hold correction information.

Then, the margin correction time stores a setup correction time indicating an increase or decrease in time of a setup margin at another temperature, and a hold correction time indicating an increase or decrease in time of a hold margin. The setup correction time and the hold correction time are, for example, empirical values acquired by practically verifying how the setup time and the hold time increase or decrease at each temperature relative to the reference temperature.

Furthermore, the correction table 130 stores the phase correction value for correction of the shift time of the reference time at another temperature based on a particular temperature. The phase correction value is, for example, an empirical value acquired by practically verifying how many steps the reference time at each temperature is shifted relative to the reference time at the reference temperature. Then, the phase correction value may be set so that the reference time during operation may be obtained by adding the time corresponding to the number of steps to the current reference time (at startup). For example, as illustrated in FIG. 14, when the reference time is set as the mean time of the valid period of data, the phase correction value is set so that the mean time at 30° C. is obtained by adding the unit time of phase correction value×1 step to the mean time at 15° C.

Then, the correction table 130 is set for each reference temperature, and is stored in the storage unit 23.

FIG. 16B is the correction table 130 at the reference temperature of 30° C. As illustrated in FIG. 16B, the setup correction time, the hold correction time, and the phase correction value store±0 corresponding to 30° C. in the correction table 130 at the reference temperature of 30° C. The setup correction time, the hold correction time, and the phase correction value at other temperatures store the increase or decrease value for the reference temperature of 30° C. and the shift value.

A specified correction time may be stored for the margin correction time as one correction time obtained by adding up the setup correction time and the hold correction time. In this case, the reference time is not set.

The extraction unit 71 of a management unit 70 illustrated in FIG. 15 refers to the correction table 130 in which the current temperature of the information processing device 2 is set as a reference temperature, and extracts the setup correction time associated with the temperature during operation of the information processing device 2. The extraction unit 71 also refers to the correction table 130 in which the current temperature of the information processing device 2 is set as a reference temperature, and extracts the hold correction time associated with the temperature during operation of the information processing device 2.

When the specified correction time is stored in the correction table 130, the extraction unit 71 refers to the correction table 130 in which the current temperature of the information processing device 2 is set as a reference temperature, and extracts the specified correction time associated with the temperature of the information processing device 2 during operation.

Furthermore, the extraction unit 71 extracts the phase correction value associated with the temperature of the information processing device 2 during operation from the correction table 130 in which the current temperature of the information processing device 2 is set as a reference temperature.

The judgment unit 63 of an information processing unit 60 judges that the memory 11 is not operating normally in the information processing device 2 when the time between the reference time and the margin start time is shorter than the time obtained by adding the setup correction time to the setup margin extracted by the extraction unit 71.

Furthermore, the judgment unit 63 judges that the memory 11 is not operating normally in the information processing device 2 when the time between the reference time and the margin end time is shorter than the time obtained by adding the hold correction time to the hold margin extracted by the extraction unit 71.

When the correction table 130 stores the specified correction time, the judgment unit 63 judges that the memory 11 is not operating normally in the information processing device 2 when the measured margin is shorter than the time obtained by adding the specified correction time to the specified margin extracted by the extraction unit 71.

The acquisition unit 62 adjusts the reference time according to the number of steps indicated by the phase correction value extracted by the extraction unit 71. In the information processing device 2 having the characteristics illustrated in FIG. 16, the acquisition unit 62 acquires the reference time during operation by shifting the reference time at startup by −2×10 (ps)=−20 (ps) under the conditions of, for example, the temperature at startup of 30° C., the temperature during operation of 40° C., and 1 step as 10 (ps).

Furthermore, the delay unit 61 sets the operation timing at the time of the reference time by adjusting the delay time of the strobe signal.

As described above, the information processing device 2 conducts a margin test on the memory 11 by assuming the setup margin and the hold margin at the temperature during operation by applying the setup correction time and the hold correction time.

Furthermore, the information processing device 2 assumes the reference time at the temperature during operation to be the reference time of the memory 11 during operation according to the reference time obtained at the current temperature.

Therefore, the information processing device 2 detects the memory 11 which may perform normally the signal processing in the information processing device 2 even if the temperature during operation is changed from the temperature at the margin test (at startup), and sets a corrected reference time as an operation timing, thereby operating normally the memory 11.

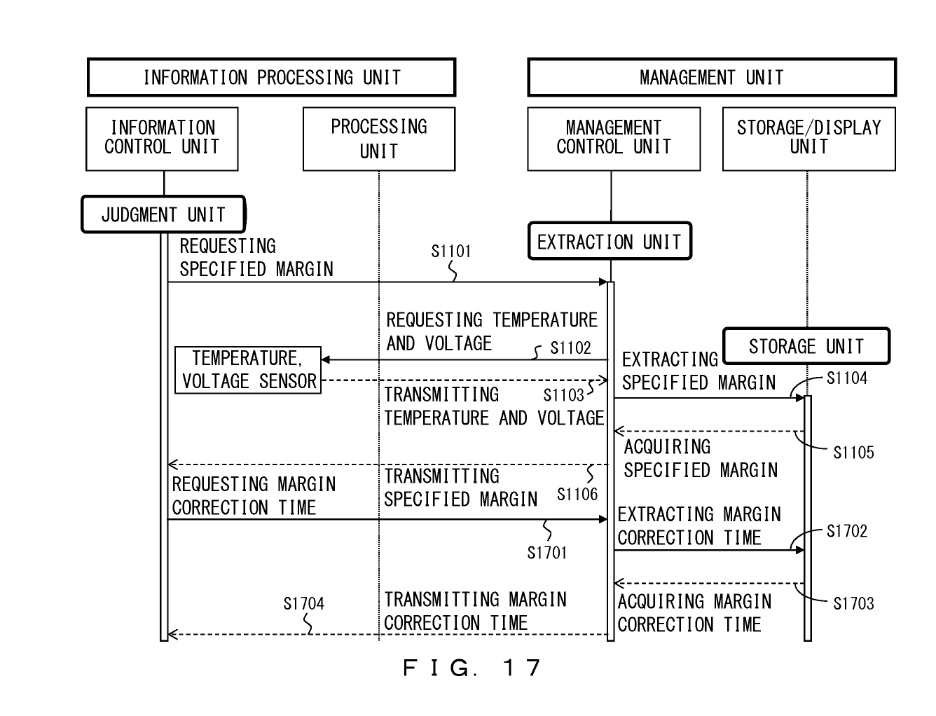

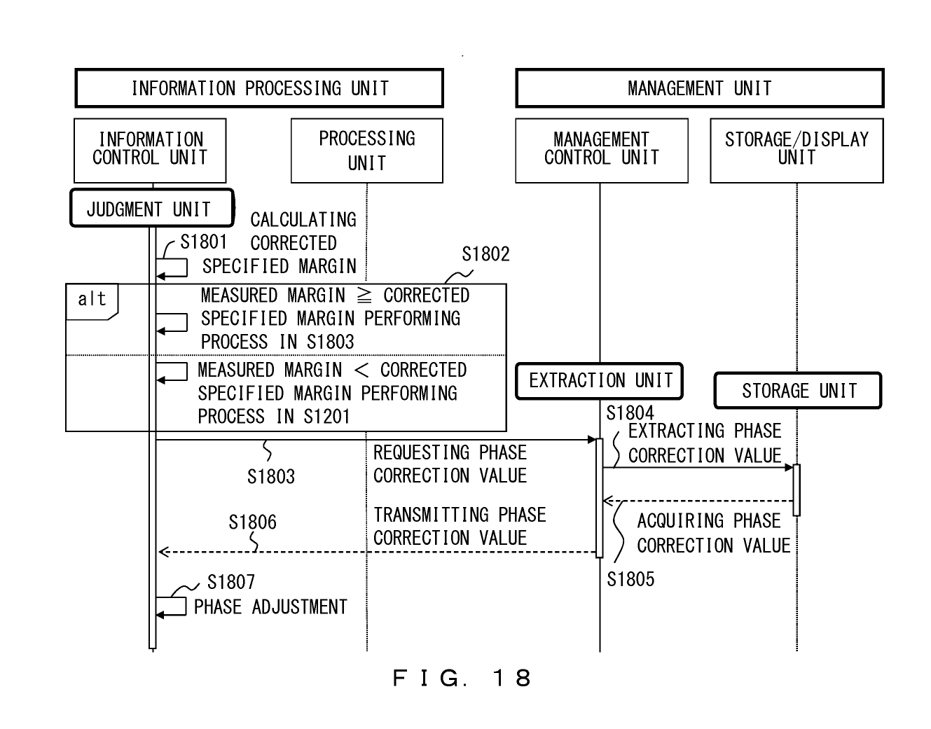

FIGS. 17 and 18 are sequences illustrating the process contents of the margin test according to the mode 2 for embodying the present invention.

The following explanation is made by assuming that the mean time of a measured margin is set as a reference time. Since the processes in S1001 through S1007, S1101 through S1106, and S1201 through S1203 are the same as those according to the mode 1 for embodying the present invention, the explanation is omitted here.

In FIG. 17, after the process in S1106, the judgment unit 63 requests that the extraction unit 71 transmit the margin correction time corresponding to the temperature of the information processing device 2 during operation of the implemented memory 11 (S1701). Then, the extraction unit 71 extracts the margin correction time associated with the temperature of the information processing device 2 during operation from the correction table 130 in which the temperature of the information processing device 2 acquired from the sensor 12 is set as the reference temperature (S1702). The temperature of the information processing device 2 during operation may be the estimated temperature input by a user. Otherwise, the temperature table which is generated in advance by practical verification in which the temperature at startup of the information processing device 2 is associated with the temperature during operation is stored in the storage unit 23. When the extraction unit 71 extracts the margin correction time, it may refer to the temperature table, and extract the temperature during operation associated with the temperature acquired from the sensor 12. The extraction unit 21 may use the temperature during operation acquired in other methods if the temperature during operation can be estimated from the temperature at startup of the information processing device 2.

Then, the extraction unit 71 acquires the margin correction time extracted in S1702 from the correction table 130 (S1703).

The extraction unit 71 transmits the acquired margin correction time to the judgment unit 63 (S1704). Thus, the judgment unit 63 acquires for the implemented memory 11 the margin correction time corresponding to the temperature during operation of the information processing device 2.

In FIG. 18, the judgment unit 63 calculates the corrected specified margin by adding the margin correction time acquired in S1704 to the specified margin (S1801). Then, it judges whether or not the measured margin acquired in S1007 includes the corrected specified margin (S1802). The judging method in S1802 is the same as the method explained above with reference to FIG. 9 excluding the replacing of the specified margin in FIG. 9 with the corrected specified margin. To be more practical, the setup correction time is added to the setup margin in FIG. 9 and the hold correction time is added to the hold margin, thereby obtaining the corrected specified margin and replacing the specified margin.

If the measured margin acquired in S1007 does not include the corrected specified margin as a result of the judgment in S1802, it is judged that the memory 11 is not operating normally in the information processing device 2, and control is passed to S1201 in FIG. 12.

When the measured margin acquired in S1007 includes the corrected specified margin as a result of the judgment in S1802, the judgment unit 63 requests that the extraction unit 71 transmit the phase correction value of the implemented memory 11 corresponding to the temperature of the information processing device 2 during operation (S1803). In this case, the judgment unit 63 judges that the memory 11 operates normally in the information processing device 2.

The extraction unit 71 extracts the phase correction value associated with the temperature of the information processing device 2 during operation from the correction table 130 in which the temperature of the information processing device 2 acquired from the sensor 12 is set as a reference temperature (S1805).

The extraction unit 71 transmits the acquired phase correction value to the judgment unit 63 (S1806). Thus, the judgment unit 63 acquires the phase correction value of the implemented memory 11 corresponding to the temperature of the information processing device 2 during operation.

Then, the judgment unit 63 changes the reference time based on the phase correction value. Furthermore, the delay unit 61 adjusts the delay time of the strobe signal so that the reference time changed by the judgment unit 63 matches the operation timing (S1807).

Thus, the information processing device 2 sets the operation timing by assuming the rising of the temperature of the information processing device 2 during operation. Then, control is passed to the process in S1201 illustrated in FIG. 12.

As described above, the information processing device 2 according to the mode 2 for embodying the present invention judges whether or not the display unit 22 implemented in the information processing device 2 operates normally in the information processing device 2 using the specified margin corrected with the influence of the temperature change taken into account by assuming that the temperature will change during operation.

Furthermore, the information processing device 2 according to the mode 2 for embodying the present invention assumes the reference time with the rising of the temperature during operation taken into account, and adjusts the operation timing during operation as the assumed reference time.

Thus, the information processing device 2 may conduct a margin test with accuracy even when the temperature at startup is different from the temperature during operation. Furthermore, since the information processing device 2 may set the operation timing so that a corrected specified margin may be included even if the temperature at startup is different from the temperature during operation, the information processing device 2 may perform the signal processing normally.

In the mode 2 for embodying the present invention, the operation timing is set as the reference time, but the operation timing may be different from the reference time. In this case, the delay unit 61 shifts the operation timing with which the signal processing may be performed normally at startup by the time period by which the judgment unit 63 has shifted the reference time. Thus, the information processing device 2 sets the operation timing so that the corrected specified margin may be included even if the temperature at startup is different from the temperature during operation as long as the operation timing allows the signal processing to be performed normally at startup, thereby performing normal signal processing.

In the information processing devices 1 and 2 according to the modes 1 and 2 for embodying the present invention, a margin test is conducted at startup, but the present invention is not limited to this application, and the margin test may be conducted at specified time intervals at a user instruction, using a timer, etc. after the operation of the information processing devices 1 and 2. Thus, even if the memory 11 becomes unable to normally perform signal processing due to the degradation of the memory 11, the memory may be detected as a memory unit subject to a fluctuation. In this case, the reference temperature may be set as the temperature of the current information processing devices 1 and 2.

All examples and conditional language recited herein are intended for pedagogical purposes to aid the reader in understanding the invention and the concepts contributed by the inventor to furthering the art, and are not to be construed as being without limitations to such specifically recited examples and conditions, nor does the organization of such examples in the specification relate to a depicting of the superiority and inferiority of the invention. Although the embodiments of the present invention have been described in detail, it should be understood that the various changes, substitutions, and alterations could be made hereto without departing from the spirit and scope of the invention.

What is claimed is:

1. An information processing device, comprising:
a storage unit which stores margin information that stores a specified margin that indicates a length for a normal operation of signal processing for a timing margin obtained by subtracting a restriction time in which the signal processing is not operating normally by setting an operation timing from a valid period in which a data signal indicates a high level or a low level, with the specified margin being associated with one or more combinations of memory information indicating one or more types of memory and environment information indicating one or more operation environments of the information processing device; and
a processor which executes a process including:
outputting a strobe signal that has a rising edge or a falling edge to memory implemented in the information processing device, and causing the memory to perform signal processing using at least one of the edges as an operation timing;
in the process of allowing the memory to perform the signal processing, changing the operation timing by changing a delay time of the strobe signal, and specifying a range of the operation timing within which the signal processing may be performed normally;
acquiring the specified range of the operation timing as a measured margin;
extracting the specified margin associated with a combination of a type of memory and an operation environment of a current information processing device from the margin information; and
judging that the memory is not operating normally in the information processing device when the acquired measured margin is shorter than the extracted specified margin.

2. The information processing device according to claim 1, wherein:
the storage unit further
stores one or more pieces of margin correction information, which stores a margin correction time indicating an increase or decrease time of the specified margin at each temperature of the information processing device using one or more particular temperatures as a reference temperature; and
the processor executes a process including:
extracting the margin correction time associated with a temperature during operation of the information processing device from the margin correction information in which a temperature of a current information processing device is set as a reference temperature; and
judging that the memory is not operating normally when the acquired measured margin is shorter than a time period obtained by adding the extracted margin correction time to the extracted specified margin.

3. The information processing device according to claim 1, wherein:
the storage unit further
stores one or more pieces of phase correction information, which stores a phase correction value indicating a change value of a phase of a strobe signal at each temperature of the information processing device using a particular temperature as a reference temperature;
the processor executes a process including:
extracting the phase correction value associated with a temperature during operation of the information processing device from the phase correction information in which a temperature of a current information processing device is set as a reference temperature; and
adjusting a delay time of the strobe signal based on the extracted phase correction value.

4. The information processing device according to claim 1, wherein:
the restriction time
includes setup time and hold time;
the specified margin
includes a setup margin in which a length of time for normal operation of the signal processing is specified for a time period between a reference time set between a margin start time after a passage of the setup time from a start time of the valid time and a margin end time at the hold time before an end time of the valid time and the margin start time; and
the processor executes a process including:
judging that memory is not operating normally in the information processing device when a time period between the reference time and the margin start time is shorter than the setup margin included in the extracted specified margin.

5. The information processing device according to claim 1, wherein:
the restriction time includes
a setup time and a hold time;
the specified margin includes
a hold margin in which a length of time for normal operation of the signal processing is specified for a time period between a reference time set between a margin start time after a passage of the setup time from a start time of the valid time and a margin end time at the hold time before an end time of the valid time and the margin end time; and
the processor executes a process including:
judging that a memory is not operating normally in the information processing device when a time period between the reference time and the margin end time is shorter than the hold margin included in the extracted specified margin.

6. The information processing device according to claim 4, wherein:
the storage unit further
stores one or more pieces of setup correction information, which stores a setup correction time indicating an increase or decrease in a time of the setup margin at another temperature as a reference of a particular temperature; and
the processor executes a process including:
extracting the setup correction time associated with a temperature of the information processing device during operation from the setup correction information in which a temperature of a current information processing device is set as a reference temperature, and
judging that the memory is not operating normally in the information processing device when a time period between the reference time and the margin start time is shorter than a time period obtained by adding the extracted setup correction time to the setup margin included in the extracted specified margin.

7. The information processing device according to claim 4, wherein:
the storage unit further
stores one or more pieces of hold correction information, which stores a hold correction time indicating an increase or decrease in a time of the hold margin at another temperature as a reference of a particular temperature; and
the processor executes a process including:
extracting the hold correction time associated with a temperature of the information processing device during operation from the hold correction information in which a temperature of a current information processing device is set as a reference temperature, and
judging that the memory is not operating normally in the information processing device when a time period between the reference time and the margin end time is shorter than a time period obtained by adding the extracted hold correction time to the hold margin included in the extracted specified margin.

8. The information processing device according to claim 4, wherein
the reference time is an intermediate time having an equal time interval from the margin start time and the margin end time .

9. The information processing device according to claim 1, wherein:
the storage unit further
stores particular data;
the signal processing
writes the particular data at a particular address of the memory, and reads data at the particular address while holding the operation timing; and
the processor executes a process including:
comparing the read data with particular data stored in the storage unit; and
judging that the signal processing is performed normally when a matching result is obtained.

10. The information processing device according to claim 1, wherein
the environment information includes at least one of a temperature of the information processing device and an operation voltage of the information processing device.

11. A memory test method used by a processor of an information processing device, the processor executing a process including:
when memory implemented in the information processing device is exchanged,
outputting a strobe signal that has a rising edge or a falling edge to the memory while stepwise changing a delay time, and causing the memory to perform signal processing using at least one of the edges as an operation timing;
acquiring a range of the operation timing within which the signal processing may be performed normally as a measured margin, which is a measured value of a timing margin obtained by subtracting restriction time in which the signal processing is not operating normally even though the operation timing is set from a valid time in which a data signal indicates a high level or a low level;
referring to margin information, which stores a specified margin indicating a length of the timing margin with which the signal processing operates normally, in association with one or more combinations of memory information indicating one or more types of memory and environment information indicating one or more operation environments of an information processing device;
extracting the specified margin associated with a combination of a type of the memory and an operation environment of the information processing device from the margin information; and
judging that the memory is not operating normally in the information processing device when the acquired measured margin is shorter than the extracted specified margin.
